(19) United States
(12) Patent Application Publication
(10) Pub. No.: US 2012/0085406 A1
(43) Pub. Date: Apr. 12, 2012

(54) SUBSTRATE WITH THIN FILM, AND SOLAR CELL USING THE SAME

(75) Inventors: Takashi Iwade, Shiga (JP); Toyoharu Terada, Shiga (JP)

(73) Assignee: TORAY ENGINEERING CO., LTD., Otsu-shi, Shiga (JP)

(21) Appl. No.: 13/378,198

(22) PCT Filed: Jul. 12, 2010
(86) PCT No.: PCT/JP10/61782

§ 371 Date: Dec. 14, 2011

(30) Foreign Application Priority Data
Jul. 22, 2009 (JP) 2009-171646

(51) Int. Cl. H01L 31/0216; B32B 3/30

(52) U.S. Cl. 136/256; 428/172

(57) ABSTRACT

A substrate with a thin film formed by layering a transparent substrate, a silicon compound film, and a transparent electroconductive film in this order, wherein the surface of the silicon compound film on the side of the transparent electroconductive film is an irregularly shaped surface provided with irregularities, the surface of the transparent electroconductive film opposite from the silicon compound film is an irregular surface shaped so as to follow the irregularly shaped surface, and the silicon compound film includes fine transparent particles having a different refractive index than the refractive index of the silicon compound film.

### TECHNOLOGICAL FIELD

The present invention relates to a substrate with a thin film, the substrate being used in particular in a solar cell and being suitable for improving the photoelectric conversion efficiency of the solar cell, and to a solar cell using the substrate.

### BACKGROUND TECHNOLOGY

Research on solar cells using silicon films has been progressing for some time and is reaching the point of practical application. Such solar cells are formed by layering a zinc oxide film or other transparent electroconductive film on a transparent substrate formed from a transparent member to form a substrate with a thin film, and layering a photoelectric conversion layer for converting light to electricity and a back electrode in this order, as shown in Patent Citation 1. In specific terms, a solar cell 100 is configured by layering a photoelectric conversion layer 103 and a back electrode 104 on a substrate 110 with a thin film configured of a transparent substrate 101 and a transparent electroconductive film 102, as shown in FIG. 3. Sunlight or other light (arrow in FIG. 3) is transmitted through the transparent substrate 101 and the transparent electroconductive film 102 and is absorbed by the photoelectric conversion layer 103, whereby electricity can be collected.

The interface between the transparent electroconductive film 102 and the photoelectric conversion layer 103 is formed with irregular shapes (textured structure 102a) in order to improve the absorption of light by the photoelectric conversion layer 103. The photoelectric conversion layer 103 can thereby absorb light efficiently. Specifically, light incident on the transparent electroconductive film 102 from the transparent substrate 101 is scattered by the irregularities, producing a so-called optical confinement effect and allowing light to be efficiently absorbed by the photoelectric conversion layer 103 (area A in FIG. 3).

### PRIOR ART CITATIONS

### Patent Citations

Patent Citation 1: Japanese Laid-open Patent Publication No. 2006-5021

### DISCLOSURE OF THE INVENTION

### Problems to be Solved by the Invention

However, in the conventional solar cell 100, problems arise in which light is not adequately absorbed even when the optical confinement effect is produced. Specifically, light reaching the transparent electroconductive film 102 is scattered by being made to strike the irregular shapes, as shown in FIG. 3, but part of the light from the transparent electroconductive film 102 is reflected by the irregular shapes, made directly incident on the transparent substrate 101, and released without being absorbed by the photoelectric conversion layer 103, as shown in area B of FIG. 3.

In particular, the irregularities of the textured structure are formed by chemical etching, CVD, sputtering, or another method, but controlling the irregular shapes in a specific manner or molding the irregularities in uniform shapes is difficult to achieve with these methods. If a formation defect is present in an irregular shape, light is reflected by the formation defect, and the percentage of light released without being absorbed by the photoelectric conversion layer 103 is increased. Accordingly, it is difficult to cause light to be absorbed by the photoelectric conversion layer 103 with the planned efficiency in the current textured structure.

An object of the present invention, which was perfected in order to solve the above-mentioned problems, is to provide a substrate with a thin film in which the absorbency of light in a photoelectric conversion layer is improved by producing an adequate optical confinement effect, and to provide a solar cell using the substrate.

### Means Used to Solve the Above-Mentioned Problems

Aimed at solving the above-mentioned problems, the substrate with a thin film according to the present invention is formed by layering a transparent substrate, a silicon compound film, and a transparent electroconductive film in this order; the substrate with a thin film characterized in that the surface of the silicon compound film on the side of the transparent electroconductive film is an irregularly shaped surface provided with irregularities, and the surface of the transparent electroconductive film opposite from the silicon compound film is an irregular surface shaped so as to follow the irregularly shaped surface; and the silicon compound film includes fine transparent particles having a different refractive index than the refractive index of the silicon compound film.

According to the substrate with a thin film, the textured structure can be formed as planned by the irregularly shaped surface, and the optical confinement effect can be improved by the presence of the fine transparent particles in the silicon compound film. In specific terms, the irregularly shaped surface (textured structure) is formed on the silicon compound film on the side near the transparent electroconductive film, and the surface shape of the silicon compound film can be controlled on a nanoscale by, for example, press molding. Specifically, forming an irregularly shaped surface on the silicon compound film by press molding or the like allows a uniform textured structure having a specified shape to be formed. The irregular surface of the transparent electroconductive film layered on the silicon compound film has a shape that follows the irregularly shaped surface, whereby the textured structure formed on the interface between the silicon compound film and the transparent electroconductive film, as well as the interface between the transparent electroconductive film and the photoelectric conversion layer, can be controlled and shaped more uniformly than a textured structure based on conventional manufacturing methods. Accordingly, incident light can be scattered by the irregular portions of the textured structure, whereby the planned optical confinement effect can be produced and improved.

Light incident on the silicon compound film is made to strike the fine transparent particles, whereupon the incident light is scattered in the silicon compound film because of the difference in the refractive index between the silicon compound film and the fine transparent particles. Specifically, the same optical confinement effect as that in the textured structure is obtained in the silicon compound film, and the light incident on the silicon compound film can therefore be prevented from being reflected on the transparent substrate, and the absorbency of light in the photoelectric conversion layer can be improved. Light propagates in the silicon compound film when reflected by the textured structure on the interface between the silicon compound film and the transparent electroconductive film. Directing the light to strike the fine transparent particles causes the light to be scattered by the fine transparent particles and reflected again on the textured structure because of the difference in the refractive indexes of the silicon compound film and the fine transparent particles. Accordingly, light can be effectively confined by the presence of the fine transparent particles in the silicon compound film even in cases in which the incident light is reflected by the irregular portions of the textured structure.

In this way, an adequate optical confinement effect can be produced because a uniform textured structure can be formed, and the absorbency of light in the photoelectric conversion layer can be improved.

The fine transparent particles are preferably distributed more unevenly away from the transparent substrate and toward the transparent electroconductive film.

In this case, light reflected by the textured structure on the interface between the silicon compound film and the transparent electroconductive film is scattered by immediately striking the fine transparent particles, is reflected again on the textured structure, and can thereby be confined in the transparent electroconductive film.

The fine transparent particles may be configured so as to be present in greater numbers in an area where the irregularly shaped surface is curved outward toward the transparent electroconductive film than in another area.

According to this configuration, the fine transparent particles are present in greater numbers in an area where the irregularly shaped surface is curved outward than in another area, whereby the surface area where the fine transparent particles are present in the silicon compound film is increased. This makes it more likely that light incident on the transparent electroconductive film will be reflected and that light incident on the silicon compound film will strike the fine transparent particles, preventing light from being released from the transparent electroconductive film on the side of the silicon compound film.

The transparent substrate and the silicon compound film can be configured so as to be formed from materials having substantially the same refractive index.

According to this configuration, light incident on the transparent substrate can be prevented from being reflected by the interface between the transparent substrate and the silicon compound film, and light incident on the transparent substrate can therefore be efficiently confined.

Aimed at solving the above-mentioned problems, the solar cell according to the present invention is characterized in being formed by layering a photoelectric conversion layer and a back electrode in this order on the transparent electroconductive film side of the substrate with a thin film.

According to the above-mentioned solar cell, an adequate optical confinement effect can be produced, and the absorbency of light in the photoelectric conversion layer can be improved.

### Effect of the Invention

According to the substrate with a thin film and the solar cell using the substrate of the present invention, the absorbency of light in the photoelectric conversion layer can be improved by producing an adequate optical confinement effect.

### BRIEF DESCRIPTION OF THE DRAWINGS

FIG. 1 is a partial cross-sectional view of the configuration of a solar cell in an embodiment of the present invention;

FIG. 2 is a partial cross-sectional view of the configuration of a substrate with a thin film in an embodiment of the present invention; and

FIG. 3 is a view showing a solar cell used in a conventional solar cell.

### PREFERRED EMBODIMENTS OF THE INVENTION

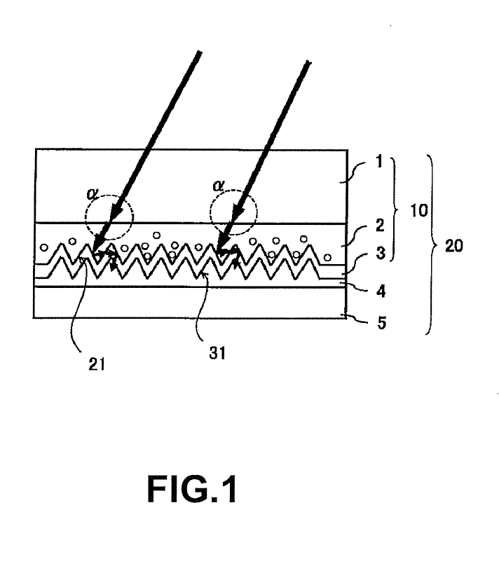

FIG. 1 is a partial cross-sectional view of the configuration of a solar cell 20 in an embodiment of the present invention.

The solar cell 20 has a transparent substrate 1, a silicon compound film 2, a transparent electroconductive film 3, a photoelectric conversion layer 4, and a back electrode 5, and is formed by the layering of these in this order, as shown in FIG. 1. Sunlight or other light (arrow in FIG. 1) is incident on the transparent substrate 1, whereupon the light is transmitted through the silicon compound film 2 and the transparent electroconductive film 3 and is made incident on the photoelectric conversion layer 4, whereby the incident light is converted to electricity.

The transparent substrate 1 protects the transparent electroconductive film 3 and the photoelectric conversion layer 4. The transparent substrate has transparency in order to supply sunlight or other light to the photoelectric conversion layer 4, and has heat resistance to withstand the heat generated in the photoelectric conversion layer 4. In the present embodiment, a generally widely available glass is used, and the surface has a substantially flat plate shape. A plastic film can also be used as long as the film is transparent and heat resistant. In this case, the production rate can be increased because the transparent substrate can be produced by wrapping.

The silicon compound film 2 (hereinafter simply referred to as the resin film 2) is designed to allow the transparent conductive film 3 to be provided with a textured structure, and has an irregularly shaped surface 21 on the side of the textured structure in contact with the transparent electroconductive film 3. Reflection of light incident on the resin film 2 by the interface between the resin film 2 and the transparent electroconductive film 3 is prevented by the irregularly shaped surface 21, and is efficiently incident on the transparent electroconductive surface 3.

In the present embodiment, the resin film 2 is formed from silicone resin containing siloxane. The siloxane-containing silicone resin is adjusted so that the refractive index thereof is substantially the same as the refractive index of the transparent substrate 1 (glass in the present invention). In specific terms, the refractive index of the glass is substantially 1.5, and the resin that forms the resin film 2 is therefore also adjusted to have a refractive index of substantially 1.5. Specifically, the film is formed so that the refractive index of the transparent substrate 1 and the refractive index of the resin film 2 are substantially the same, and light incident on the transparent substrate 1 is therefore allowed to be directly incident on the resin film 2 without being reflected by the interface between the transparent substrate 1 and the resin film 2. Accordingly, more light is supplied to the photoelectric conversion layer 4 than in cases in which the refractive indexes of the transparent substrate 1 and the resin film 2 are different from each other, and the absorbency of light in the photoelectric conversion layer 4 can therefore be improved.

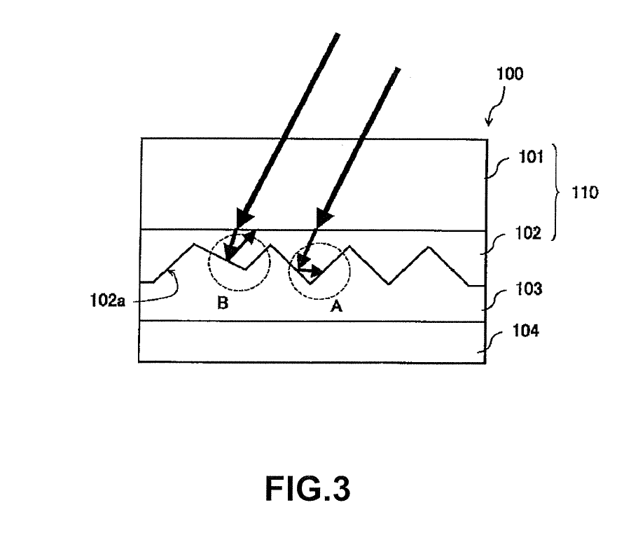

A comparison will now be made with the conventional solar cell 100 in FIG. 3. Glass is conventionally used as the transparent substrate 101, and zinc oxide is layered on the glass substrate as the transparent electroconductive film 102. In this case, the refractive index of the glass substrate is 1.5, the refractive index of the zinc oxide is 1.9, and the reflectance is therefore approximately 1.4%. Accordingly, 1.4% of light incident on the transparent substrate 1 is reflected. Specifically, in the configuration of the present embodiment, in which the refractive indexes of the transparent substrate 1 and the resin film 2 are made substantially the same, the absorbency of light can be improved 1.4% in a straightforward manner in comparison with the conventional configuration. When it is considered that the conversion efficiency of the solar cell 20 is generally 6 to 8%, an improvement of 1.4% is a large improvement.

The materials for the transparent substrate 1 and the resin film 2 are different, and completely matching the refractive indexes thereof is therefore difficult. However, “approximately the same” refers to a situation in which the refractive index of the resin film 2 ranges from −0.1 to +0.1, and preferably from −0.05 to +0.05, in relation to the refractive index of the transparent substrate 1. Reflection loss at the interface is considered to be substantially absent as long as the refractive index is within this range.

A siloxane-containing silicone resin has a more stable molecular structure than a siloxane-free silicone resin, and shape stability after processing is therefore excellent. Accordingly, stable processing and shaping can be achieved even with a fine and complex textured structure having a high optical confinement effect.

The irregularly shaped surface 21 can be formed on the resin film 2 by imprinting. Specifically, an uncured siloxane-containing silicone resin is applied to a separate printed base on which the irregular shape of the textured structure is formed, and the resin is then cured under heat and pressure or by ultraviolet irradiation. The printed base is then detached to transfer the irregular shape of the textured structure to the silicone resin. The irregularly shaped surface 21 is thereby formed on the resin film 2. A nanoscale irregular pattern can thus be transferred to the silicone resin by forming, for example, the irregular pattern on the printed base. The desired textured structure is thereby uniformly formed with greater ease than in the case of conventional chemical etching, CVD, or sputtering. The optical confinement effect can thereby be easily obtained as planned, and the absorbency of light in the photoelectric conversion layer 4 can be improved.

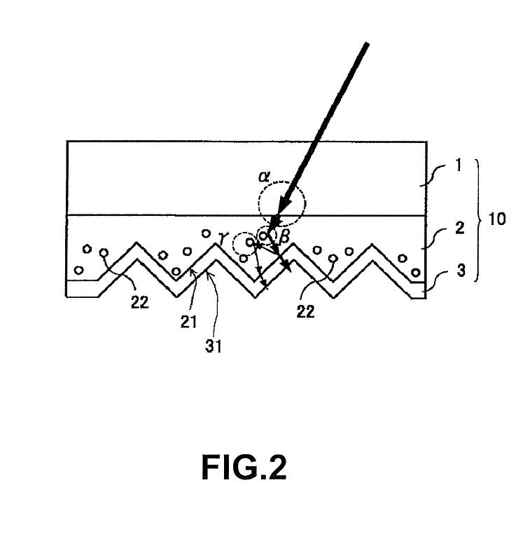

Fine transparent particles 22 having a different refractive index than the refractive index of the resin film 2 are included in the resin film 2. FIG. 2 is a partial cross-sectional view of the configuration of a substrate 10 with a thin film having the resin film 2, which contains the fine transparent particles 22. In the present embodiment, high-purity zinc oxide made into fine transparent particles at the nano-level is contained in the resin film 2. Light incident on the resin film 2 can thereby be efficiently absorbed by the transparent electroconductive film 3, and hence the photoelectric conversion layer 4.

Specifically, the refractive index of the fine transparent particles 22 is 1.9, as opposed to the refractive index of the resin film 2, which is 1.5. Incident light is therefore refracted, transmitted, and partially scattered when the light incident on the resin film 2 is made to strike the fine transparent particles 22. The incident light is scattered by the fine transparent particles 22, and is thereby made incident (β portion) on the transparent electroconductive film 3. In addition, the incident light is reflected by the fine transparent particles 22, and is thereby again made incident (γ portion) on the transparent electroconductive film 3 even if the incident light is reflected by the transparent electroconductive film 3 (even if the light is reflected by the textured structure). Accordingly, the absorbency of light in the photoelectric conversion layer 4 can be improved by the optical confinement effect of the fine transparent particles 22 contained in the resin film 2.

The fine transparent particles 22 may be configured so as to be present evenly in the resin film 2, but are preferably distributed unevenly toward the transparent electroconductive film 3. Specifically, distributing the fine transparent particles 22 unevenly near the irregularly shaped surface 21 makes it more likely that the light will be absorbed by the transparent electroconductive film 3 when light reflected by the interface with the transparent electroconductive film 3 is reflected again by the fine transparent particles 22, and the absorbency of light in the photoelectric conversion layer 4 can be improved as a result. Moreover, the surface area of the resin film 2 in which the fine transparent particles 22 are present is increased when the fine transparent particles 22 are present in greater numbers in an area where the irregularly shaped surface 21 is curved outward toward the transparent electroconductive film 3 than in another area. This makes it more likely that the light incident on the transparent electroconductive film 3 will be reflected, and the light incident on the resin film 2 will strike the fine transparent particles 22, and the release of light from the transparent electroconductive film 3 on the side of the resin film 2 can therefore be effectively prevented.

The resin film 2 in which the fine transparent particles 22 are thus present in greater numbers toward the transparent electroconductive film 3 can be formed, for example, by applying a silicone resin a plurality of times in separate operations when a silicone resin is applied to the aforedescribed printed base. Specifically, a silicone resin including the fine transparent particles 22 is first applied to a printed base on which the aforedescribed textured structure is formed. A silicone resin lacking the fine transparent particles 22 is then applied on top of the previous resin, making it possible to form a resin film 2 in which the fine transparent particles 22 are present in greater numbers toward the transparent electroconductive film 3. The resin is not limited to two applications, and may be applied a plurality of times, in which case the resin film may be formed so that the number of the fine transparent particles 22 is gradually increased toward the printed base by applying a silicone resin that includes the fine transparent particles 22 whose concentration increases toward the printed base. Light incident on the resin film 2 can thereby be prevented from immediately striking and reflecting off of the fine transparent particles 22.

The fine transparent particles 22 may be tin oxide fine transparent particles, and may be any particles that are transparent and have a different refractive index than the refractive index of the resin film 2.

In FIG. 1, the transparent electroconductive film 3 is an electrode film for collecting electricity generated by the photoelectric conversion layer 4. The transparent electroconductive film 3 is formed by zinc oxide and has transparency. In addition, the surface of the transparent electroconductive film 3 opposite the resin film 2 is formed as an irregular surface 31.

The irregular surface 31 has a textured structure, and light incident on the transparent electroconductive film 3 is incident on the photoelectric conversion layer 4 with high efficiency due to the optical confinement effect. The irregular surface 31 has a shape that follows the irregularly shaped surface 21. Specifically, the transparent electroconductive film 3 is deposited on the irregularly shaped surface 21 of the resin film 2 by sputtering or the like, whereby a very thin zinc oxide film is evenly formed on the irregularly shaped surface 21. The transparent electroconductive film 3 having a constant thickness that follows the irregularly shaped surface 21 is thereby formed. Accordingly, a textured structure is formed both on the surface of the transparent electroconductive film 3 on the side of the resin film 2, and on the surface of the transparent electroconductive film on the side of the photoelectric conversion layer 4.

The substrate 10 with a thin film is thus formed by layering the resin layer 2 and the transparent electroconductive film 3 in this order on the transparent substrate 1. The solar cell 20 can be obtained by layering the photoelectric conversion layer 4 and the back electrode 5 in this order on the transparent electroconductive film 3 of the substrate 10 with a thin film.

The photoelectric conversion layer 4 has a PN junction or a PIN junction to convert incident light to electricity. A silicon material or the like can be used for the photoelectric conversion layer 4, and the material can be deposited and formed on the transparent electroconductive film 3 by CVD or the like.

The back electrode 5 is an electrode film for collecting electricity generated by the photoelectric conversion layer 4, and the electrode causes light that has been transmitted through without being absorbed by the photoelectric conversion layer 4 to be returned to the photoelectric conversion layer 4. In specific terms, an aluminum film, silver film, or other reflective metal film can be used, and light that has been transmitted through the photoelectric conversion layer 4 can be returned to the photoelectric conversion layer 4 by reflection from the metal. A zinc oxide film or another transparent electroconductive film 3 layered on a metal layer can be used for the back electrode 5.

When the aforedescribed solar cell 20 is irradiated with sunlight, the light is made incident on the transparent substrate 1 and is made directly incident (a portion in FIGS. 1 and 2) on the resin film 2 without being reflected by the interface between the transparent substrate 1 and the resin film 2. The light incident on the resin film 2 is then diffused by striking the irregularities of the textured structure formed on the resin film 2 and the transparent electroconductive film 3, and is made incident on the transparent electroconductive film 3 due to the optical confinement effect. Specifically, the light incident on the transparent substrate 1 directly reaches the irregularities of the textured structure formed on the resin film 2 and the transparent electroconductive film 3 without loss from reflection between the different layered members, and is made incident on the transparent electroconductive film 3 due to the optical confinement effect. The light incident on the transparent electroconductive film 3 is then made to strike the irregularities of the textured structure formed on the interface between the transparent electroconductive film 3 and the photoelectric conversion layer 4, and is thereby subjected to the optical confinement effect and is made incident on and absorbed by the photoelectric conversion layer 4.

According to the substrate 10 with a thin film and the solar cell 20 using the substrate in the present embodiment, intermediate reflection of light incident on the transparent substrate 1 can be minimized, an adequate optical confinement effect can be produced by allowing the formation of a textured structure having a uniform shape, and the absorbency of light in the photoelectric conversion layer 4 can be improved.

### KEY TO SYMBOLS

1: Transparent substrate

2: Silicon compound film (resin film)

3: Transparent electroconductive film

4: Photoelectric conversion layer

5: Back electrode

10: Thin film substrate

20: Solar cell

21: Irregularly shaped surface

22: Fine transparent particles

31: Irregular surface

1. A substrate comprising:
with a thin film formed by layering a transparent substrate;
a silicon compound film; and
a transparent electroconductive film,
the silicon compound film being configured between the transparent substrate and the transparent electroconductive film;
a surface of the silicon compound film facing the transparent electroconductive film and being non-flat with a pattern,
a surface of the transparent electroconductive film facing opposite to the silicon compound film and being non-flat with the pattern; and
the silicon compound film including fine transparent particles having a first refractive index different from a second refractive index of the silicon compound film.

2. The substrate according to claim 1, wherein
the fine transparent particles are configured closer to the transparent electroconductive film than to the transparent substrate.

3. The substrate according to claim 1, wherein
the silicon compound film is curved in an area and bulges towards the transparent electroconductive film,
the fine transparent particles are present in greater numbers in the area.

4. The substrate according to claim 1, wherein
the transparent substrate is made a material having a third refractive index, and
the second refractive index is substantially equal to the third refractive index.

5. A solar cell comprising:
a photoelectric conversion layer;
a back electrode; and
the substrate according to claim 1,
the photoelectric conversion layer being configured between the back electrode and the substrate.
